(19) United States
(12) Patent Application Publication
(10) Pub. No.: US 2002/0071995 A1
(43) Pub. Date: Jun. 13, 2002

(54) Photoresist topcoat for deep ultraviolet (DUV) direct write laser mask fabrication

(76) Inventors: Melvin Warren Montgomery, Camas, WA (US); Jeffrey A. Albelo, Hillsboro, OR (US); Zoilo Cheng Ho Tan, Cupertino, CA (US)

Correspondence Address: PATENT COUNSEL, Legal Affairs Dept., Applied Materials, Inc., BOX 450A, Santa Clara, CA, 95052, US

(21) Appl. No.: 09/904,454

(22) Filed: Jul. 12, 2001

Related U.S. Application Data
(63) Continuation-in-part of application No. 09/293,713, filed on Apr. 16, 1999.

(51) Int. Cl. G03F 9/00

(52) U.S. Cl. 430/5

(57) ABSTRACT

A coating is provided over a fresh layer of resist, such as a chemically amplified resist (CAR). The overcoat stabilizes process control and makes it possible to precoat the CAR on wafer or mask blanks some time prior to exposure.

### CROSS REFERENCE TO RELATED APPLICATIONS

This application is a continuation-in-part of application Ser. No. 09/293,713, filed Apr. 16, 1999, which is hereby incorporated by reference in its entirety as if fully set forth herein.

### BACKGROUND OF THE INVENTION

1. Field of the Invention

This invention relates the lithography and more specifically to lithography using chemically amplified resists.

2. Description of the Related Art

Lithography is a well known technique, especially in the semiconductor field, and involves coating a substrate which is, e.g., a semiconductor wafer or a reticle substrate with a layer of resist. The resist is sensitive to exposing energy which is typically either ultraviolet light, laser light, X rays or an electron beam. Portions of the resist are exposed and the remainder is not exposed. This is accomplished either by scanning a beam of the light or electrons across the resist to define patterns or, in the case of exposing certain types of wafers, applying the radiation through a partially transmissive mask, thereby to expose only non-masked portions of the resist.

The resist is subsequently developed and the unexposed regions are either removed or remain, with the complementary exposed portions either remaining or being removed depending on whether the resist works in negative tone or positive tone, respectively. Thereby the exposure patterns the resist on the substrate.

Subsequent steps typically involve ion implantation or etching or oxide growth so that the resist pattern is transferred into the underlying material. This is either the underlying substrate or, in the case of a mask, a thin layer of, for instance, chromium metal applied between the resist and the substrate which is thereby partially removed to form a mask.

Lithography is thus used for making devices (for instance, either semiconductor devices or micro machined devices) and for making masks used in photolithography for exposure of other wafers. There are many well known formulations of resist for both electron beam exposure and light exposure at various wavelengths, as well as X-ray exposure. One category of enhanced sensitivity resists called chemically amplified resist (CAR) has been known for many years. CAR involves, e.g., an acid catalyzation process. Many variations of chemically amplified resists are commercially available primarily for 257 nm, 248 nm, and 193 nm deep ultraviolet (DUV) light lithography application. Many of these CARs have been used in electron beam light lithography.

It is known that resists and especially CAR is sensitive to certain environmental contaminants, thus rendering their use for both wafer fabrication and for mask fabrication somewhat problematic and requiring special handling. This includes exposure and development very soon after application. It has been found that CAR deteriorates in terms of lithographic performance as soon as one hour (or less) after its application. Of course this undesirably increases cost. It also has limited use of the otherwise beneficial CAR.

An additional problem associated with the use of resists such as chemically amplified resists is that of standing waves, which results from interference by a reflecting wave with the incoming wave. One method typically used to ameliorate the standing wave problem is to apply a post exposure bake (PEB). However, this does not always resolve the problem. Finally, certain resists may also be sensitive to variations in substrate stoichiometry.

Examples of positive tone CAR are APEX, UVIIHS, rJV5, and UV6 manufactured by Shipley Co., Inc., AZ DX11000P, DX1200P and DX1300P manufactured by Clariant Corporation, ARCH 8010 and ARCH 8030 manufactured by Arch Chemicals, ODUR-1010 and ODtJR-1013 manufactured by Tokyo Ohka Kogyo Co., Ltd. and PEK11OA5 manufactured by Sumitomo Chemicals, Inc. Examples of negative tone CAR are SAL-60I, SAL-603 manufactured by Shipley Co., Inc., EN-009 PG manufactured by Tokyo Ohka Kogyo Co., Ltd., and NEB 22 manufactured by Sumitomo Chemicals, Inc.

Therefore, it would be desirable to improve the usability and storability of chemically amplified resist applied on a substrate by finding ways to reduce the undesirable effects thereon of environmental contaminants.

### SUMMARY OF THE INVENTION

In accordance with this invention, the environmental sensitivity of resist is eliminated, or at least substantially reduced, by overcoating a chemically amplified (or other) resist with a thin coating of a protective but transmissive material. This allows long term storage (e.g., up to four months or longer) of unexposed resist applied to a substrate. The coating in some embodiments is an electric charge-dissipation (conductive) material. Although non-conductive material can also be used, it may be advantageous, particularly in electron beam exposure, to use a conductive overcoat.

A conductive coating provides two desirable functions. These are, first, charge dissipation during electron beam exposure for accurate overlay of two successive layers in multilevel mask making, and, second, maintaining the shelf life and therefore stability of lithographic performance (in terms of critical dimension and integrity) of the resist, e.g., for a day, a week, a month, or months (at least four months as determined by experiment) after its application. Shelf life is not limited to mere storage, but includes, e.g., time spent in transit. This is a substantial improvement, since as stated above normally CAR formulations are subject to undesirable performance changes within minutes of application. Thus such an unexposed coated substrate (wafer or reticle) becomes an article of manufacture and of commerce rather than merely a transitory result of a process. This opens up a new business manufacturing opportunity of commerce (inter- or intracompany) in such articles of manufacture, not available heretofore.

Thus desirably such overcoated resist can be prepared on the substrate (wafer or reticle) months before its actual exposure, in contrast to present use of CAR which requires application immediately prior to the exposure. Of course, this means that one company (or location) can manufacture the resist coated wafers or reticle blanks, and another company (or location) can then later perform the exposure, in contrast to present practice.

An example of a charge dissipation coating material is any suitable conductive material which can be readily applied, for instance, a thin layer of an initially liquid organic conductive material (which dries) such as polyaniline, or a thin layer of a metal such as chromium or aluminum suitably applied. However, as noted above, any suitable material (charge dissipative or non-charge dissipative) which may be effective as a diffusion barrier (i.e., which may prevent diffusion of contaminants) may be employed as the overcoat. For example, in deep UV direct write laser mask fabrication, the material sold under the trade name AZ Aquatar III, sold by Clariant Corporation, may be employed to coat an entire mask prior to imaging.

The exposing electron beam typically is operated 25 at or greater than 10,000 volts accelerating voltage and therefore can have a penetration range (through the coating material) on the order of about one micron to several microns below the resist surface. In the case of light exposure, the metal conductive coating layer will not be applicable.

### BRIEF DESCRIPTION OF THE DRAWINGS

A better understanding of the invention is obtained when the following detailed description is considered in conjunction with the following drawings in which:

FIG. 1 shows a mask blank with applied layers of CAR and charge dissipation material being exposed to a beam of exposing radiation in accordance with an embodiment of the present invention.

FIG. 2 is a conceptual process flow diagram of a method in accordance with an embodiment of the present invention.

### DETAILED DESCRIPTION OF THE INVENTION

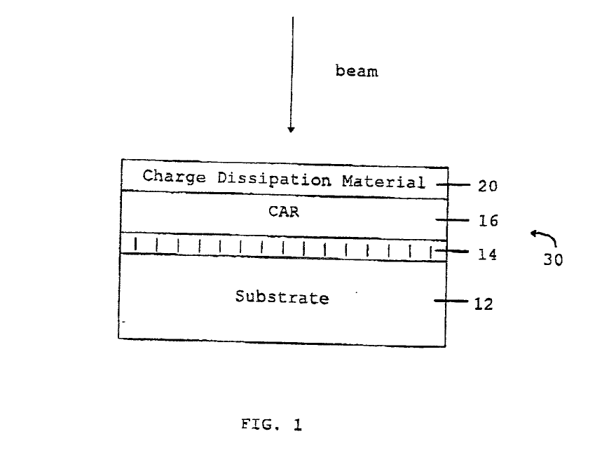

The result of the above-described process of applying a layer of protective material over a CAR layer is illustrated in FIG. 1 which shows a conventional substrate 12 which, for instance, is the quartz or glass substrate (blank) used for making masks on which is conventionally a thin layer of metal such as chromium 14, which is the mask layer to be patterned. Overlying these is the CAR layer 16 applied to a conventional thickness dependent on factors such as the CAR formulation and exposure technique.

Structures 12, 14 and 16 may be wholly conventional. An additional layer 20 is applied over the CAR layer 16. Layer 20 is in some embodiments of a charge dissipation material. This material is applied subsequent to application of the CAR layer 16 and while the CAR layerl6 is fresh (before it is subject to environmental contamination). Then, later, structure 30 is exposed to actinic radiation, for instance a scanning electron beam or actinic (exposing) light in a conventional lithographic machine. In any case, the CAR is a formulation selected to be sensitive to the particular exposing radiation. Note that while a beam of exposing radiation is depicted here, this is not required. In lithography using a mask to expose a semiconductor wafer, the exposing radiation is not a focused beam.

In the case of a semiconductor wafer, the chromium layer 14 is not present on the substrate 12, which then would typically be crystalline silicon. However, in other respects use of the coating material layer 20 is the same in both the case of fabricating wafers and making a mask as depicted in FIG. 1. As described above, advantageously the protective layer 20 also provides electric charge dissipation during an electron beam exposure, since the electrons are dissipated through layer 20 rather than building up on the otherwise exposed upper surface of CAR layer 16. (Resists are generally electrically insulative.) This charge dissipation has been found to be beneficial for accurate overlay when one is forming a mask with two successive layers in multilevel mask making, as in the fabrication of phase shift masks where some chromium is removed in the image areas, thereby rendering it nonconductive when the second level is exposed. (See Tan publication referenced below.) The protective layer is transmissive of the exposing radiation. A thin metal coating layer (typically 100-200A thick) is transmissive of an electron beam. If the actinic exposure is other than an electron beam, the overcoat material is chosen so that it is transmissive to the wavelength of exposure, such as 257 nm, 248 nm, or 193 nm deep ultraviolet light.

Also, whether the exposing radiation beam is light or electrons, the presence of the protective layer improves the shelf life of the underlying CAR layer by shielding the CAR layer from environmental contaminants (including air and moisture). The coating layer 20 of course in any case is transmissive to the incident radiation.

The following describes fabrication of the structure 30 of FIG. 1 and its use. The formation of chromium layer 14 on substrate 12 is conventional, as is the subsequent overlay of the CAR layer 16. To the freshly prepared CAR layer 16 (which has typically been conventionally soft baked), a thin coating of a charge dissipation material 20 is applied. Examples of application of charge dissipation material are first spin coating a thin (800 to 2000A) layer of liquid organic conductive material (water-soluble conductive polymer), such as a polyaniline, commercially available as PanAquas (from IBM Corp) or Aquasave (from Nitto Chemicals). See “Conducting polyanilines: Discharge layers for electron-beam lithography”, Marie Angelopoulos et al., J.VAC.SCI.TECHNOL.B 7(6), (November/December 1989), pp.1519-1523, incorporated herein by reference in its entirety. Such water-soluble materials can be removed (after exposure of the resist) by rinsing in distilled water. Such a film has a conductivity of −0.1/ohm-cm.

Alternatively, the charge dissipation coating is a thin metal layer 20 formed by evaporating or sputtering, for instance, to a thickness of 100 to 200A. Examples of suitable metals are chromium and aluminum. The coating material is selected to have no chemical effect on the resist. For further detail on an example of application of charge dissipation material on resist, see “Application of charge dissipation material on MEBES® phase shift mask fabrication”, Zoilo C. H. Tan et al., SPIE Vol. 2322 Photomask Technology and Management (1994), pp. 141-148, incorporated herein by reference in its entirety. Structure 30 is conventionally exposed (some time—minutes to months—later) using the electron beam or actinic light as in FIG. 1. Suitable systems for exposing the structure 30 include the MEBES and ALTA series systems, available from ETEC Systems, Inc., Hayward, Calif. A subsequent post exposure bake is also conventional.

Then the upper layer 20 is stripped, e.g., by rinsing in deionized water which removes the organic conductive material. Another example, if the layer 20 is chromium, is stripping with a suitable acidic etching fluid. If layer 20 is aluminum, it similarly is removed by etching with alkaline etchant.

Next is development of the exposed CAR layer 16. This is conventional using whatever developer technique is suitable for the particular CAR formulation. If the development is performed using an alkaline developer formulation, this may by itself also remove the layer 20, if layer 20 is aluminum. In other words, the application of the alkaline developer to structure 30 would initially dissolve the protective layer 20 and then perform the actual development of the underlying CAR layer 16. This process therefore is exposure, bake, remove layer 20, develop resist. Alternately, after exposure to actinic radiation, the upper layer 20 is stripped as described above, to be followed with post exposure bake and development of the underlying CAR layer 16 (expose, remove, bake, develop).

As noted above, the coating may also be embodied as a non-charge dissipative layer and, in particular, any material suitable for use as a diffusion barrier (i.e., to prevent diffusion of airborne contaminants), for example, in direct write laser mask fabrication application. An example of such a material is AZ Aquatar III, available from Clariant Corporation. Use of such a material provides improvements in eliminating standing waves, protection of the resist from airborne contamination, and elimination of sensitivity to variations is substrate stoichiometry. In one embodiment, improved CD (critical feature) uniformity is achieved through selection of the material having an index of refraction matched to the index of refraction of the resist. For example, the index of refraction of the layer may be approximately equal to the square root of the index for the resist. In such an embodiment, light reflected off the substrate bottom and then internally back off the top of the protective layer and the top of the resist layer is generally equal in intensity.

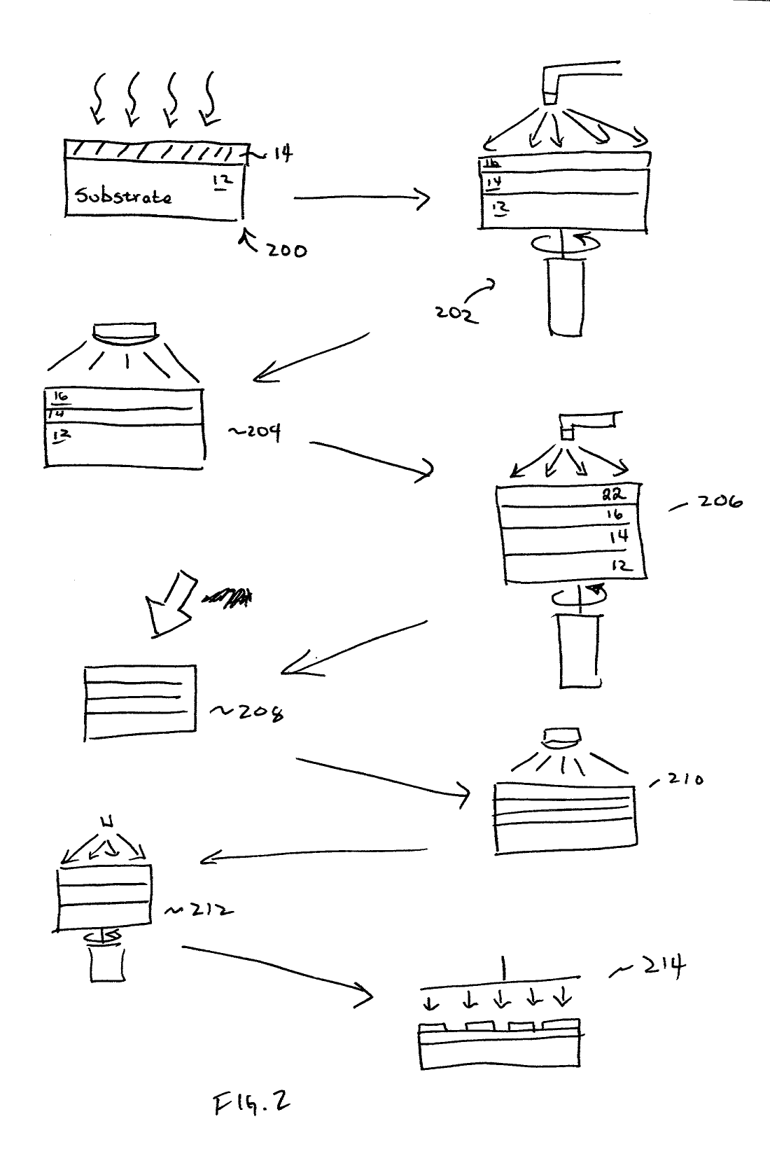

Fabrication of such a structure is explained with reference to FIG. 2. At 200, a substrate 12 has applied to it a metal layer 14. The substrate 12 may conventionally be fused silica. The metal layer 14 is the material in which the pattern is eventually formed. Typically, the metal layer is chromium and typically has a thickness of about 600 to 1000 angstroms. The chromium may be deposited by sputtering.

In 202, the resist 16, such as a chemically amplified resist, is applied. The resist 16 may have a thickness of about 2500 to about 5000 angstroms and may be applied by spin coating. A suitable resist 16 is the DX1100 resist, available from Clariant Corporation. The mask is soft-baked at 204 (referred to as a “post apply bake (PEB)”) to remove solvents remaining in the resist film. Next, at 206, the coating 22 is applied. For instance, a layer about 450 angstroms thick may be applied by spin coating at about 1550 RPM and spinning dry in air. As noted above, the coating 22 may be any material suitable for use as a diffusion barrier and, in particular, one such material is the material sold under the trade name AZ Aquatar III by Clariant Corporation. The coating 22 affords contaminant protection and critical dimension (CD) uniformity, as well as alleviating the standing wave problem.

Next, at 208, the mask is imaged using, for example, an ALTA laser writing system, available from ETEC Systems, Inc. As in the case of FIG. 1, the imaging may occur some time after the application of the resist and coating. In 210, the mask is subject to a post-exposure bake (PEB). At 212, the mask is then developed using a suitable developer. The developer may also be effective to remove the coating 22. One advantage of a protective layer is that it may improve developer wetting and therefore achieve more optimal developing. Otherwise, the coating would be removed prior to developing. Finally, at 214, the metal film is patterned, such as by planar plasma etching or reactive ion etching.

This disclosure is illustrative and not limiting. The particular materials disclosed and the parameters of their use are also illustrative and not limiting; one of ordinary skill in the field will appreciate that various substitutions and modifications can be made. In any case, such modifications or substitutions are intended to fall within the scope of the appended claims.

What is claimed is:

1. A method of preparing a substrate for storage and subsequent lithographic exposure, comprising:
forming a layer of environmentally sensitive resist over a principal surface of the substrate;
forming a layer of protective material over the resist layer before the resist layer is subject to substantial environmental contamination and before lithographic properties of said layer of environmentally sensitive resist can substantially deteriorate due to said environmental contamination, said forming a layer of protective material comprising spin coating said layer and spinning dry in air; and
exposing the resist to radiation after forming the layer of protective material.

2. The method of claim 1, said layer of protective material comprising a diffusion barrier.

3. The method of claim 2, said layer of protective material comprising a diffusion barrier.

4. The method of claim 3, wherein the substrate is transmissive of exposing energy and wherein there is a layer of material non-transmissive of the exposing energy over the substrate and under the resist layer.

5. The method of claim 4, further comprising: baking the resist layer prior to forming the layer of protective material.

6. A method for preparing a mask, comprising:
applying a metal layer to a substrate;
applying a resist layer to said metal layer;
applying a layer of diffusion barrier protective material to said resist layer;
exposing said mask to radiation;
developing said resist; and
etching said metal layer.

7. A method in accordance with claim 6, said applying a layer of diffusion barrier comprising applying said layer to an entire surface of said mask.

8. A method in accordance with claim 7, said diffusion barrier comprising a layer about 450 angstroms thick.

9. A method of preparing, storing and lithographically exposing a substrate, comprising:
forming a layer of environmentally sensitive chemically amplified resist over a principal surface of the substrate;
forming a layer of protective material over the resist layer before the resist layer is subject to substantial environmental contamination and before lithographic properties of said layer of chemically amplified resist can substantially deteriorate due to said environmental contamination, said layer of protective material comprising a diffusion barrier;
storing the substrate with the protective material and resist layer for at least oneday;
after the storage, exposing the substrate to exposing energy, thereby exposing selected portions of the resist through the layer of protective material;
removing at least part of the layer of protective material; and
developing the exposed resist after removing.

10. The method of claim 9, wherein forming the layer of protective material comprises one of spin coating, evaporating, or sputtering.

11. The method of claim 10, further comprising:
baking the resist layer prior to forming the layer of protective material.

12. The method of claim 11, wherein the substrate is transmissive of exposing energy and wherein there is a layer of material non-transmissive of the exposing energy over the substrate and under the resist layer.

13. The method of claim 12, wherein the removing comprises one of rinsing and etching.

14. The method of claim 13, wherein the removing precedes the developing.

15. The method of claim 14, wherein the removing takes place at the same time as the developing.

16. A method for deep ultraviolet direct write laser mask fabrication, comprising:
applying a metal layer to a substrate;
applying a resist layer to said metal layer;
applying a layer of diffusion barrier protective material to said resist layer;
exposing said mask to said laser;
developing said resist; and
etching said metal layer.
